(19) United States
(12) Patent Application Publication
(10) Pub. No.: US 2023/0146952 A1
(43) Pub. Date: May 11, 2023

(54) TRANSISTOR WITH FACETED, RAISED SOURCE/DRAIN REGION

(71) Applicant: GLOBALFOUNDRIES U.S. Inc., Malta, NY (US)

(72) Inventors: George R. MULFINGER, Gansevoort, NY (US); Matthew W. STOKER, Ballston Lake, NY (US); Ryan W. SPORER, Mechanicville, NY (US); Man GU, Malta, NY (US)

(21) Appl. No.: 17/521,076

(22) Filed: Nov. 8, 2021

(51) Int. Cl. H01L 29/417; H01L 29/16

(52) U.S. Cl. CPC H01L 29/41783; H01L 29/1608

(57) ABSTRACT

The present disclosure relates to semiconductor structures and, more particularly, to transistors with faceted raised source/drain regions and methods of manufacture. The structure includes: a substrate; a gate structure on the substrate; and faceted, raised source/drain regions adjacent to the gate structure and including at least two different semiconductor materials.

### BACKGROUND

The present disclosure relates to semiconductor structures and, more particularly, to transistors with faceted, raised source/drain regions and methods of manufacture.

As semiconductor processes continue to scale downwards, e.g., shrink, the desired spacing between features (i.e., the pitch) also becomes smaller. To this end, in the smaller technology nodes it becomes ever more difficult to fabricate features due to the critical dimension (CD) scaling and process capabilities.

For example, fully depleted silicon on insulator (FDSOI) structures require certain parameters for radio frequency (RF) applications. These parameters include lower gate to source/drain capacitance, lower gate resistance and higher drive current (DC) performance/conductance. However, conventional technologies are unable to co-optimize these parameters. Generally, conventional technologies have silicidation regions which encroach too closely to the underlying buried oxide (BOX) layer, thereby increasing resistance and degrading device performance (Ron). Also, in conventional technologies, there is processing variability resulting in overlap capacitance (Coy) variability and inconsistent source/drain formation.

### SUMMARY

In an aspect of the disclosure, a structure comprises: a substrate; a gate structure on the substrate; and faceted, raised source/drain regions adjacent to the gate structure and comprising at least two different semiconductor materials.

In an aspect of the disclosure, a structure comprises: a gate structure comprising a silicided region; and a faceted, raised source/drain regions adjacent to the gate structure and comprising a stack of epitaxial semiconductor materials and a silicided region partially into the faceted, raised source/drain regions.

In an aspect of the disclosure, a method comprises: forming a gate structure on a substrate; and forming a faceted, raised source/drain regions adjacent to the gate structure and comprising at least two different semiconductor materials.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a transistor (gate structure), amongst other features, and respective fabrication processes in accordance with aspects of the present disclosure.

FIG. 2 shows raised source/drain regions, amongst other features, and respective fabrication processes in accordance with aspects of the present disclosure.

FIG. 3 shows alternative raised source/drain regions, amongst other features, and respective fabrication processes in accordance with aspects of the present disclosure.

FIG. 4 shows a silicide on the raised source/drain regions, amongst other features, and respective fabrication processes in accordance with aspects of the present disclosure.

FIG. 5 shows contact formation to the raised source/drain regions and the gate structure, amongst other features, and respective fabrication processes in accordance with aspects of the present disclosure.

### DETAILED DESCRIPTION

The present disclosure relates to semiconductor structures and, more particularly, to transistors with faceted, raised source/drain regions and methods of manufacture. More specifically, the faceted, raised source/drain regions comprise layers of different semiconductor materials. In embodiments, the different semiconductor materials may (i) control the facet height (and/or shape) of the raised source/drain region, (ii) prevent overlap of the raised source/drain onto an adjacent gate structure (e.g., limit and control growth against sidewalls of the gate structure), and (iii) control the diffusion of silicide contacts into the faceted raised source/drain region, e.g., maintain an adequate distance between an underlying insulator layer and channel region of the gate structure. Accordingly and advantageously, the use of the different materials for the raised source/drain regions reduce overlap capacitance (Cov) and Cov variability, in addition to providing improved RF performance variability.

In more specific embodiments, the transistor can be an NFET fully depleted semiconductor on insulator (FDSOI) device or a PFET FDSOI device. Both of the FDSOI devices include faceted, raised epitaxial source/drain regions. In embodiments, the raised epitaxial source/drain regions may be fabricated using a multi-stage epitaxial growth process comprising at least two different semiconductor materials. By way of example, the two different semiconductor materials may be SiP and SiGe, with the SiGe having a different epitaxial growth rate in the <111> plane than the SiP. In embodiments, the semiconductor materials, e.g., SiGe, with the slower epitaxial growth rate can be used to control the facet height (and/or shape) and reduce overlap onto the adjacent gate structure, i.e., reduce Coy and Coy variability.

The combination of different materials can also be used to control the diffusion rate of the silicide into the raised epitaxial source/drain region. As to this latter feature, the diffusion control allows the silicide to remain spaced away from the channel region of the gate structure and an underlying insulator material, i.e., provide a concave silicide layer ensuring that the raised source/drain regions do not encroach on the channel region of the gate structure.

The transistors of the present disclosure can be manufactured in a number of ways using a number of different tools. In general, though, the methodologies and tools are used to form structures with dimensions in the micrometer and nanometer scale. The methodologies, i.e., technologies, employed to manufacture the transistors of the present disclosure have been adopted from integrated circuit (IC) technology. For example, the structures are built on wafers and are realized in films of material patterned by photolithographic processes on the top of a wafer. In particular, the fabrication of the transistors uses three basic building blocks: (i) deposition of thin films of material on a substrate, (ii) applying a patterned mask on top of the films by photolithographic imaging, and (iii) etching the films selectively to the mask.

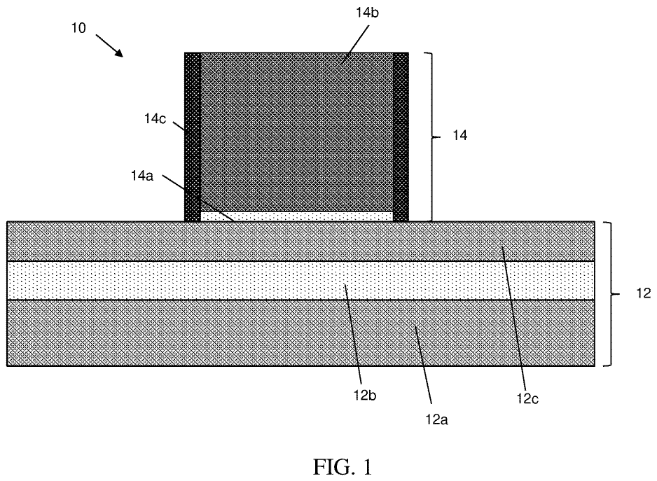

FIG. 1 shows a transistor (gate structure), amongst other features, and respective fabrication processes. In particular, the structure 10 of FIG. 1 includes a substrate 12 and a transistor 14 (e.g., gate structure) formed on the substrate 12. In embodiments, the substrate 12 comprises a semiconductor-on-insulator (SOI) substrate. More specifically, the substrate 12 includes a semiconductor handle wafer 12a, an insulator layer 12b and a semiconductor layer 12c on the insulator layer 12b. In the SOI implementation, the semiconductor handle wafer 12a provides mechanical support to the insulator layer 12b and the semiconductor layer 12c. Alternatively, the substrate 12 may be a single semiconductor material such as bulk silicon.

In the SOI implementation, the semiconductor handle wafer 12a and the semiconductor layer 12c may be composed of any suitable semiconductor material including, but not limited to, Si, SiGe, SiGeC, SiC, GaAs, InAs, InP, and other III/V or II/VI compound semiconductors. Moreover, the semiconductor handle wafer 12a and the semiconductor layer 12c may comprise any suitable crystallographic orientation (e.g., a (100), (110), (111), or (001) crystallographic orientation). Alternatively, the semiconductor layer 12c may be formed using a smart cut process where two semiconductor wafers are bonded together with an insulator material between the two semiconductor wafers.

The insulator layer 12b may include a dielectric material such as silicon dioxide, silicon nitride, silicon oxynitride, boron nitride or a combination thereof. In a preferred embodiment, the insulator layer 12b may be a buried oxide layer (BOX). The insulator layer 12b may be formed by a deposition process, such as CVD, PECVD or physical vapor deposition (PVD). In another embodiment, the insulator layer 12b may be formed using a thermal growth process, such as thermal oxidation, to convert a surface portion of the semiconductor handle wafer 12a to an oxide material. In yet another embodiment, the insulator layer 12b may be formed by implanting oxygen atoms into a bulk semiconductor substrate and thereafter annealing the structure.

Still referring to FIG. 1, the gate structure 14 may be formed on the substrate 12 by a gate first process. In a gate first process, for example, a gate dielectric material 14a and polysilicon material 14b are deposited on the substrate 12, followed a patterning process. In embodiments, the gate dielectric material 14a can be either a low-k dielectric material, e.g., oxide, or a high-k gate dielectric material, e.g., HfO₂ Al₂O₃, Ta₂O₃, TiO₂, La₂O₃, SrTiO₃, LaAlO₃, ZrO₂, Y₂O₃, Gd₂O₃, and combinations including multilayers thereof. In further embodiments, a metallization stack, e.g., workfunction metal (e.g., TiN), may be provided between the gate dielectric material 14a and the polysilicon material 14b, depending on the application and design parameters.

In embodiments, the gate dielectric material 14a and polysilicon material 14b may be formed by a deposition method such as CVD or PVD, for example. The patterning process may be conventional lithography and etching processes known to those of skill in the art. For example, a resist formed over the polysilicon material 14b is exposed to energy (light) to form a pattern (opening). An etching process with a selective chemistry, e.g., reactive ion etching (RIE), will be used to transfer the pattern from the resist layer to both the polysilicon material 14b and the gate dielectric material 14a.

Following the resist removal by a conventional oxygen ashing process or other known stripants, sidewall spacers 14c are formed on the patterned gate structure 14. The sidewall spacers 14c may comprise a low-k dielectric material such as nitride or oxide. The low-k dielectric material may be deposited on the gate structures 14 using a conventional CVD process, followed by anisotropic etching processes to remove any material from horizontal surfaces of the structure.

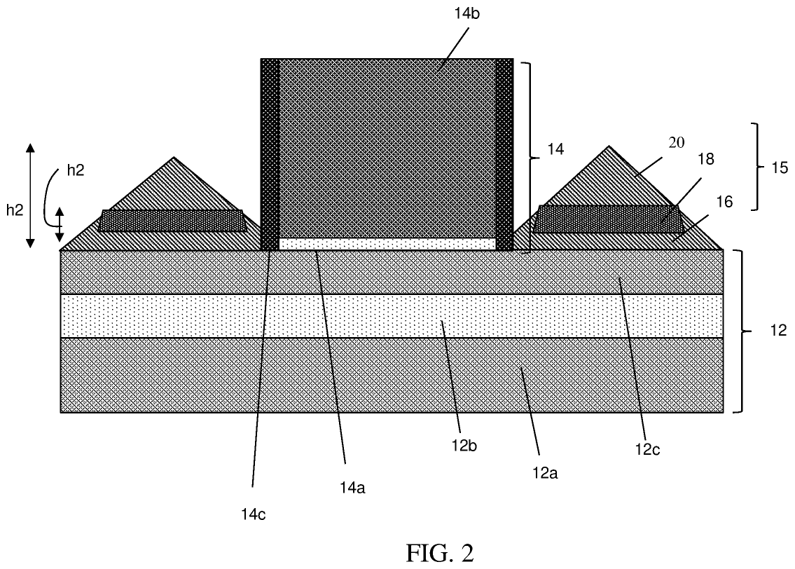

In FIG. 2, source/drain regions 15 are formed on the substrate 12 adjacent to the gate structure 14. More particularly, the source/drain regions 15 are raised source/drain regions 15 formed by a multiple stage epitaxial growth process, which forms a facetted profile, e.g., tapered profile. For example, the multiple stage epitaxial growth process may comprise the deposition (growth) of two or more semiconductor materials, e.g., semiconductor materials 16, 18, 20. In embodiments, the semiconductor materials 16 and 20 may be the same material, e.g., Si, SiC, SiP or SiCP; whereas the semiconductor material 18 may be another semiconductor material with a slower growth rate in the <111> plane. For example, the semiconductor material 18 may comprise SiGe or amorphous silicon. In any of these embodiments, the multiple stage epitaxial growth process provides a consistent growth pattern, resulting in consistent faceted source/drain regions 15 from device to device. Also, in embodiments, the upper semiconductor material, e.g., semiconductor materials 18, 20 may be remote from sidewalls of the gate structure 14.

In embodiments, the height (h1) of the semiconductor material 18 may be approximately 4 nm for an approximate 30 nm height of the source/drain regions 15. In further embodiments, the height (h2) of the entire stack of materials of the source/drain regions 15 can be between approximately 10 nm to 30 nm; although other dimensions are also contemplated herein.

In embodiments, the slower epitaxial growth rate of the semiconductor material 18 may be used to control facet height and/or facet shape. More specifically, the slower epitaxial growth rate of the semiconductor material 18 will pin down (e.g., control) the overall height of the raised source/drain regions 15. In this way, it is possible to provide greater facet height control of the raised source/drain regions 15. In addition, the semiconductor material 18 may be used to control (limit) and/or prevent overgrowth of semiconductor material on the sidewalls 14c of the gate structure 14. In this way, the

Accordingly, the use of the semiconductor material 18 may reduce overlap capacitance (Coy) and Coy variability by controlling facet height, in addition to providing improved RF performance variability. It should be understood by one of ordinary skill in the art that Coy is a measure of the capacitance between the gate structure 14 and the source/drain regions 15. Also, an interface or boundary may form at least between the semiconductor materials 16, 18 which may prevent diffusion of silicide into the lower semiconductor material 16. This feature will ensure that the silicide stays away (e.g., does not encroach) from the insulator layer 12b, which reduces current crowding in the channel region of the gate structure 14.

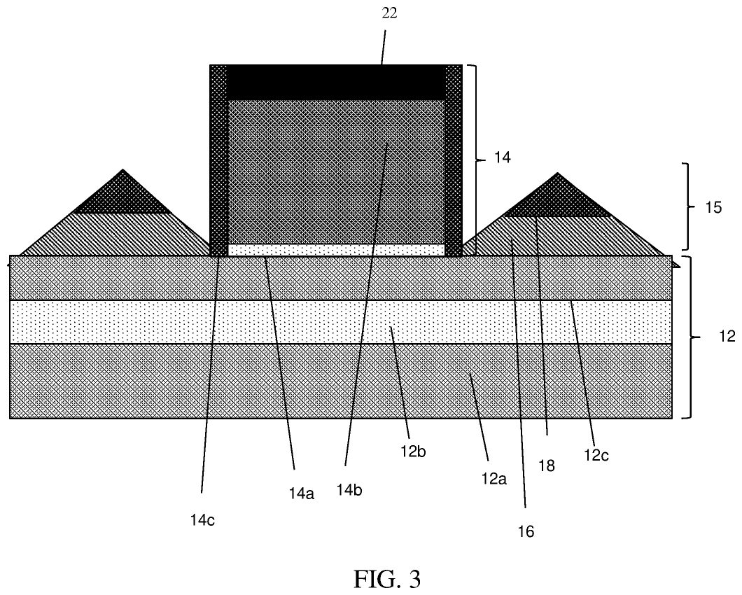

FIG. 3 shows another embodiment in which the source/drain regions 15 are formed on the substrate 12 adjacent to the gate structure 14 with only two materials 16, 18. As with the previous embodiment shown in FIG. 2, the two materials 16, 18 will have different properties and will also form faceted, raised source/drain regions 15. Also, as with the previous embodiment shown in FIG. 2, the materials 16, 18 may be formed by a multiple stage epitaxial growth process. In embodiments, the semiconductor material 16 may be, e.g., Si, SiC, SiP or SiCP, and the semiconductor material 18 may be another semiconductor material, e.g., SiGe or amorphous silicon. The above noted advantages can also be obtained in this embodiment, e.g., reduced Coy and Coy variability.

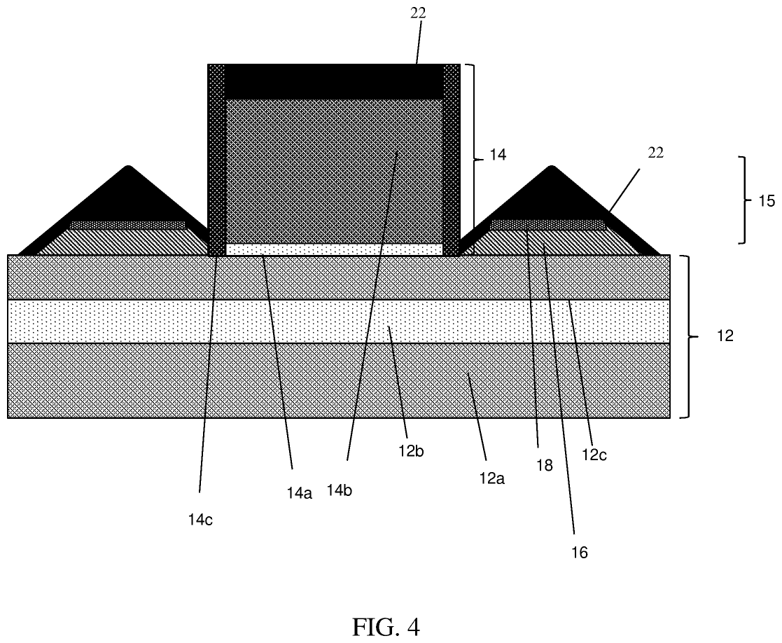

FIG. 4 shows a silicide 22 on the source/drain regions 15 and the gate structure 14. The silicide 22 may be thinner on the source/drain regions 15 than the gate structure 14. As should be understood by those of skill in the art, the silicide process begins with deposition of a thin transition metal layer, e.g., nickel, cobalt or titanium, over fully formed and patterned semiconductor devices (e.g., source and drain regions 15 and respective devices 14). After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts 22 in the active regions of the device.

In either embodiment of FIG. 2 or FIG. 3, the diffusion of the silicide slows down within the material 18 (compared to material 16 or 20) and, in embodiments, stops at the interface of the different materials 16, 18. More specifically, the diffusion (e.g., formation) of the silicide contacts 22 will slow down at the interface of the different materials 16, 18, ensuring that the silicide contacts 22 will not encroach on the insulator layer 12b. In this way, the silicide contacts 22 may have a concave profile, with the silicide contacts 22 being further away from the buried insulator layer 12b at a center (middle) than at the edges, e.g., near the gate structure 14. Accordingly, due to this profile, it is now possible to prevent current crowding in the channel region of the gate structure 14. The location of the silicide contacts 22 on the raised source/drain regions 15 may also lower gate resistance, in addition to preventing overlap onto the gate structure 14, e.g., limit and control growth against sidewalls of the gate structure 14.

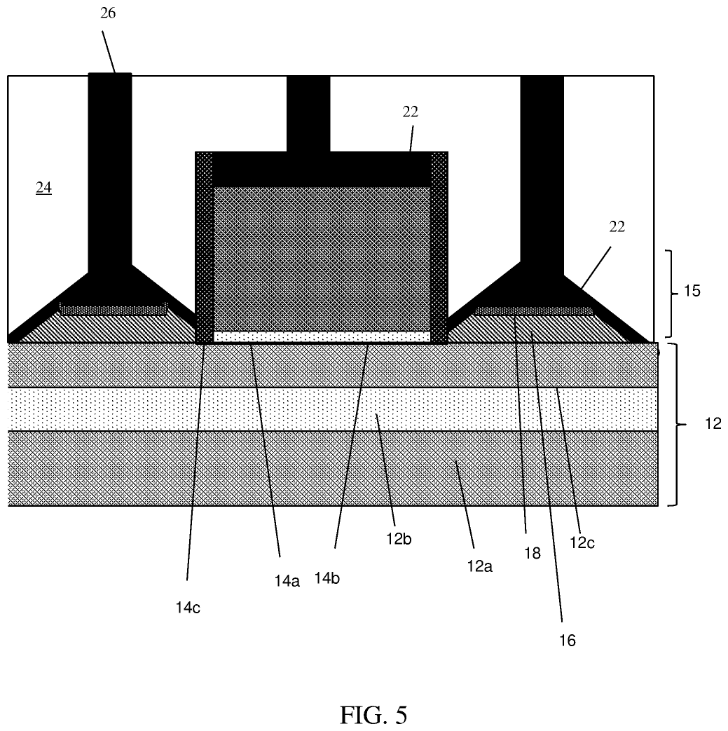

FIG. 5 shows contact formation to the raised source/drain regions 15 and the gate structure 14. More specifically, contacts 26 are formed in a dielectric material 24 using conventional lithography, etching and deposition processes. For example, a dielectric material 24 may be deposited over the structure using a conventional deposition process, e.g., CVD. The dielectric material 24 may be any appropriate interlevel dielectric material including, e.g., a multi-stack of nitride and oxide materials. The dielectric material 24 is subjected to an etching process to form trenches to expose the silicide contacts 22 of the raised source/drain regions 15 and the gate structure 14. A conductive material may be formed (e.g., deposited) within the trenches to form the contacts 26. In embodiments, the conductive material may be, for example, aluminum or tungsten.

The transistors can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a substrate;
a gate structure on the substrate; and
faceted, raised source/drain regions adjacent to the gate structure and comprising at least two different semiconductor materials.

2. The structure of claim 1, wherein the at least two different semiconductor materials comprise epitaxial Si and epitaxial SiGe.

3. The structure of claim 1, wherein the at least two different semiconductor materials comprise an upper semiconductor material, a middle semiconductor material and a lower semiconductor material, and the middle semiconductor material comprises a slower growth rate in a <111> plane than the upper semiconductor material and the lower semiconductor material.

4. The structure of claim 3, wherein the middle semiconductor material comprises a different silicide diffusion rate than the upper semiconductor material.

5. The structure of claim 3, wherein a junction between the middle semiconductor material and the lower semiconductor material prevents diffusion of silicide completely within the lower semiconductor material.

6. The structure of claim 3, wherein the upper semiconductor material and the lower semiconductor material comprise a same semiconductor material and the middle semiconductor material comprises a different semiconductor material.

7. The structure of claim 6, wherein the upper semiconductor material and the lower semiconductor material comprise one of Si, SiC, SiP and SiCP, and the middle semiconductor material comprises SiGe.

8. The structure of claim 3, further comprising silicide on the faceted, raised source/drain regions and the gate structure, wherein the silicide on the faceted, raised source/drain regions comprises a concave profile such that the silicide at a center is farther away from the substrate than at edges.

9. The structure of claim 1, wherein an upper portion of the faceted, raised source/drain regions are remote from sidewalls of the gate structure.

10. The structure of claim 1, wherein the faceted, raised source/drain regions comprise two semiconductor materials with different silicide diffusion rates.

11. The structure of claim 10, wherein the two semiconductor materials comprise an upper semiconductor material comprising SiGe and a lower semiconductor material comprising one of Si, SiC, SiP and SiCP.

12. A structure comprising:
a gate structure comprising a silicided region; and
a faceted, raised source/drain regions adjacent to the gate structure, the faceted, raised source/drain regions comprising a stack of epitaxial semiconductor materials and a silicided region partially into the faceted raised source/drain regions.

13. The structure of claim 12, wherein the stack of epitaxial semiconductor material comprises a first semiconductor material, a second semiconductor material and a third semiconductor material, the second semiconductor material being between the first semiconductor material and the third semiconductor material, and the second semiconductor material comprising a slower <111> growth rate than the first semiconductor material and the third semiconductor material.

14. The structure of claim 13, wherein the second semiconductor material comprises SiGe.

15. The structure of claim 13, wherein a height of the faceted, raised source/drain regions is confined by the second semiconductor material.

16. The structure of claim 13, wherein the second semiconductor material comprises a slower silicide diffusion rate than the third semiconductor material.

17. The structure of claim 16, wherein the silicided region of the faceted, raised source/drain regions comprises a concave profile such that the silicide region in a middle of the profile is farther away from an underlying substrate than at edges of the profile.

18. The structure of claim 12, wherein the stack of epitaxial semiconductor material comprises a first semiconductor material and a second semiconductor material which comprises a slower growth rate than the first semiconductor material in a <111> plane.

19. The structure of claim 12, wherein an upper semiconductor material of the stack of epitaxial semiconductor material are remote from sidewalls of the gate structure.

20. A method comprising:
forming a gate structure on a substrate; and
forming faceted, raised source/drain regions adjacent to the gate structure and comprising at least two different semiconductor materials.
